(19) United States
(12) Patent Application Publication
(10) Pub. No.: US 2025/0294673 A1
(43) Pub. Date: Sep. 18, 2025

(54) WIRING SUBSTRATE

(71) Applicant: SHINKO ELECTRIC INDUSTRIES CO., LTD., Nagano (JP)

(72) Inventor: Tatsuro YOSHIDA, Nagano (JP)

(21) Appl. No.: 19/072,311

(22) Filed: Mar. 6, 2025

(30) Foreign Application Priority Data
Mar. 12, 2024 (JP) 2024-037942

(51) Int. Cl. H05K 1/02; H05K 1/03

(52) U.S. Cl. CPC H05K 1/0298; H05K 1/0306; H05K 2201/068; H05K 2201/09827; H05K 2201/10204

(57) ABSTRACT

A wiring substrate includes a glass core layer; first and second wiring layers on first and second surfaces, respectively, of the glass core layer; first and second organic insulating layers covering the first and second wiring layers, respectively; first dummy pads provided one in each of corner areas of the first surface and electrically independent of the first wiring layer, second dummy pads provided one in each of corner areas of the second surface and electrically independent of the second wiring layer, and dummy through vias piercing through the glass core layer to connect the first and second dummy pads. In each corner area of the first surface, the distance from the apex of the corner area to the center of the nearest dummy through via is less than or equal to 17 times the maximum width of the dummy through vias at the first surface in a plan view.

### CROSS-REFERENCE TO RELATED APPLICATION

This application is based upon and claims priority to Japanese Patent Application No. 2024-037942, filed on Mar. 12, 2024, the entire contents of which are incorporated herein by reference.

### FIELD

A certain aspect of the embodiment discussed herein is related to wiring substrates.

### BACKGROUND

In recent years, wiring substrates including a glass core layer have been attracting attention. (See, for example, Japanese Laid-open Patent Publication No. 2016-219683.)

### SUMMARY

According to an aspect, a wiring substrate includes a glass core layer; first and second wiring layers on first and second surfaces, respectively, of the glass core layer; first and second organic insulating layers covering the first and second wiring layers, respectively; first dummy pads provided one in each of corner areas of the first surface and electrically independent of the first wiring layer, second dummy pads provided one in each of corner areas of the second surface and electrically independent of the second wiring layer, and dummy through vias piercing through the glass core layer to connect the first and second dummy pads. In each corner area of the first surface, the distance from the apex of the corner area to the center of the nearest dummy through via is less than or equal to 17 times the maximum width of the dummy through vias at the first surface in a plan view.

The object and advantages of the invention will be realized and attained by means of the elements and combinations particularly pointed out in the claims.

It is to be understood that both the foregoing general description and the following detailed description are exemplary and explanatory and not restrictive of the invention, as claimed.

### BRIEF DESCRIPTION OF DRAWINGS

FIGS. 1A and 1B are diagrams illustrating a wiring substrate according to an embodiment;

FIGS. 2A and 2B are diagrams illustrating part of the glass core layer of the wiring substrate according to the embodiment;

FIGS. 3A through 3G are diagrams illustrating a process of manufacturing a wiring substrate according to the embodiment;

FIG. 4 is a plan view of part of the glass core layer of a wiring substrate according to a variation of the embodiment; and

FIG. 5 illustrates a simulation.

### DESCRIPTION OF EMBODIMENT

Some of wiring substrates including a glass core layer use an inexpensive organic material as an interlayer insulating material. However, organic materials and copper interconnects have coefficients of thermal expansion (CTEs) greater than the coefficient of thermal expansion of the glass core layer. Therefore, the mismatch of coefficients of thermal expansion may cause cracks in the glass core layer.

According to an embodiment, cracks are less likely to be caused in the glass core layer of a wiring substrate.

One or more embodiments of the present invention will be explained below with reference to the accompanying drawings. In the following, the same elements or components are referred to using the same reference numerals, and duplicate description thereof may be omitted.

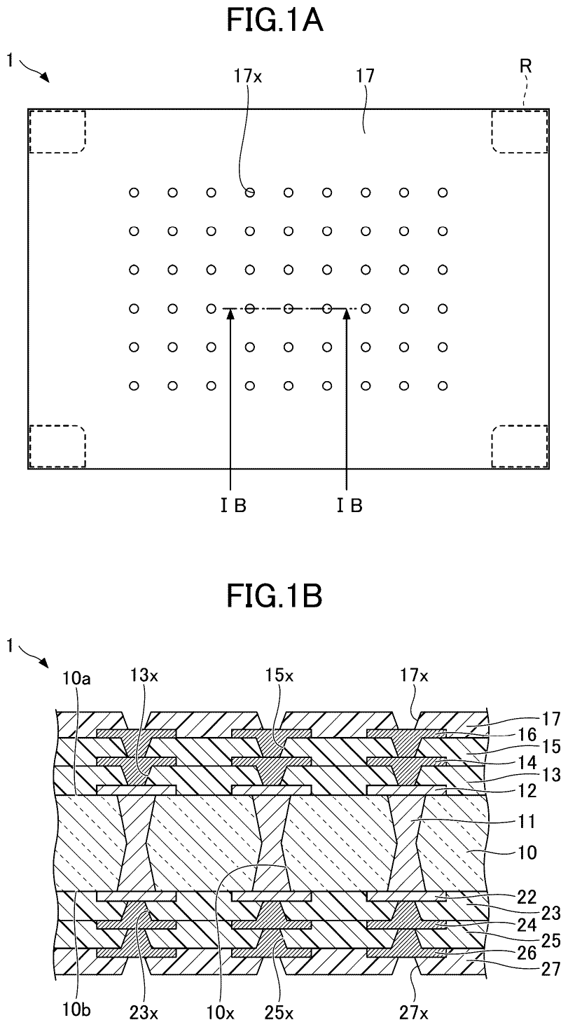

FIG. 1A is a plan view of a wiring substrate according to an embodiment, and FIG. 1B is a sectional view of part of the wiring substrate of FIG. 1A, taken along the line IB-IB.

Referring to FIGS. 1A and 1B, a wiring substrate 1 includes a glass core layer 10 and wiring layers and insulating layers that are stacked on each side of the glass core layer 10. The wiring substrate 1 has a laminated structure symmetrical with respect to the glass core layer 10.

Specifically, the wiring substrate 1 includes a wiring layer 12, an insulating layer 13, a wiring layer 14, an insulating layer 15, a wiring layer 16, and a solder resist layer 17 that are successively stacked on a first surface 10a of the glass core layer 10. Furthermore, the wiring substrate 1 includes a wiring layer 22, an insulating layer 23, a wiring layer 24, an insulating layer 25, a wiring layer 26, and a solder resist layer 27 that are successively stacked on a second surface 10b of the glass core layer 10. The number of stacked wiring layers and the number of stacked insulating layers are not limited to those illustrated in the example of FIGS. 1A and 1B, and may be determined as desired.

According to the embodiment, for convenience, the solder resist layer 17 side of the wiring substrate 1 is referred to as “upper side” or “first side,” and the solder resist layer 27 side of the wiring substrate 1 is referred to as “lower side” or “second side.” Furthermore, with respect to each part or component of the wiring substrate 1, a surface on the solder resist layer 17 side is referred to as “upper surface” or “first surface” and a surface on the solder resist layer 27 side is referred to as “lower surface” or “second surface.” The wiring substrate 1, however, may be used in an inverted position or oriented at any angle. Furthermore, a plan view refers to a view of an object in a direction normal to the first surface 10a of the glass core layer 10, and a planar shape refers to the shape of an object as viewed in a direction normal to the first surface 10a of the glass core layer 10.

A general-purpose glass substrate may be used as the glass core layer 10. Any glass material such as soda lime glass, borosilicate glass, quartz glass or the like may be used with no particular restrictions as the material of the general-purpose glass substrate. The thickness of the glass core layer 10 is, for example, approximately 300 μm to approximately 2000 μm. Through holes 10x piercing through the glass core layer 10 in its thickness direction are formed in the glass core layer 10. The through holes 10x have a circular planar shape, for example. Furthermore, the through holes 10x have a sectional shape of, for example, an hourglass shape, gradually narrowing toward a narrower portion in the center in the thickness direction from a wider portion at each of the first surface 10a and the second surface 10b of the glass core layer 10. The through holes 10x may have a rectangular sectional shape, for example.

The wiring layer 12 is formed on the first surface 10a of the glass core layer 10. Furthermore, the wiring layer 22 is formed on the second surface 10b of the glass core layer 10. The wiring layer 12 and the wiring layer 22 are electrically connected by through vias 11 formed in the through holes 10x. The wiring layers 12 and 22 are patterned into respective predetermined planar shapes. For example, copper (Cu) or the like may be used as the material of the wiring layers 12 and 22 and the through vias 11. The thickness of each of the wiring layers 12 and 22 is, for example, approximately 10 μm to approximately 40 μm. The wiring layer 12, the wiring layer 22, and the through vias 11 may be formed as a one-piece structure. The wiring layer 12 is a typical example of a first wiring layer according to the embodiment. The wiring layer 22 is a typical example of a second wiring layer according to the embodiment.

The insulating layer 13 is an interlayer insulating layer formed on the first surface 10a of the glass core layer 10 to cover the wiring layer 12. For example, a non-photosensitive thermosetting resin whose main component is an organic material such as epoxy resin or polyimide resin may be used as the material of the insulating layer 13. A photosensitive thermosetting resin whose main component is an organic material such as acrylic resin may also be used as the material of the insulating layer 13. The insulating layer 13 may contain filler such as silica (SiO₂). The thickness of the insulating layer 13 is, for example, approximately 20 μm to approximately 40 μm.

The insulating layer 13 includes via holes 13x that are openings. The via holes 13x pierce through the insulating layer 13 to expose part of the upper surface of the wiring layer 12. The via holes 13x are, for example, recesses having the shape of an inverted truncated cone, having an upper opening at the upper surface of the insulating layer 13 and a lower opening at the upper surface of the wiring layer 12. The upper opening is greater in diameter than the lower opening. The insulating layer 13 is a typical example of a first insulating layer according to this embodiment.

The wiring layer 14 fills in the via holes 13x to be electrically connected to the wiring layer 12, and extends onto the upper surface of the insulating layer 13 from within the via holes 13x. Specifically, the wiring layer 14 includes via interconnects that fill in the via holes 13x and wiring patterns formed on the upper surface of the insulating layer 13. The wiring patterns of the wiring layer 14 are electrically connected to the wiring layer 12 via the via interconnects. The material and the wiring pattern thickness of the wiring layer 14 are, for example, the same as the material and the thickness, respectively, of the wiring layer 12.

The insulating layer 15 is an interlayer insulating layer formed on the upper surface of the insulating layer 13 to cover the wiring layer 14. The material and the thickness of the insulating layer 15 are, for example, the same as the material and the thickness, respectively, of the insulating layer 13. The insulating layer 15 may contain filler such as silica. The insulating layer 15 includes via holes 15x that are openings. The via holes 15x pierce through the insulating layer 15 to expose part of the upper surface of the wiring layer 14. The via holes 15x are, for example, recesses having the shape of an inverted truncated cone, having an upper opening at the upper surface of the insulating layer 15 and a lower opening at the upper surface of the wiring layer 14. The upper opening is greater in diameter than the lower opening.

The wiring layer 16 fills in the via holes 15x to be electrically connected to the wiring layer 14, and extends onto the upper surface of the insulating layer 15 from within the via holes 15x. Specifically, the wiring layer 16 includes via interconnects that fill in the via holes 15x and wiring patterns formed on the upper surface of the insulating layer 15. The wiring patterns of the wiring layer 16 are electrically connected to the wiring layer 14 via the via interconnects. The material and the wiring pattern thickness of the wiring layer 16 are, for example, the same as the material and the thickness, respectively, of the wiring layer 12.

The solder resist layer 17 is a protective insulating layer that is the outermost layer on the first side of the wiring substrate 1, and is formed on the upper surface of the insulating layer 15 to cover the wiring layer 16. The solder resist layer 17 includes openings 17x. Part of the upper surface of the wiring layer 16 is exposed in the openings 17x. The openings 17x may have a circular planar shape, for example. The wiring layer 16 exposed in the openings 17x may be used as pads for electrical connections to a semiconductor chip or the like. For example, a photosensitive insulating resin whose main component is phenolic resin, polyimide resin or the like may be used as the material of the solder resist layer 17. The solder resist layer 17 may contain filler such as silica. The thickness of the solder resist layer 17 is, for example, approximately 20 μm to approximately 40 μm.

A surface treatment layer (not depicted) may be formed on the upper surface of the wiring layer 16 exposed in the openings 17x. Examples of the surface treatment layer include a gold (Au) layer, a nickel (Ni)/Au layer (a laminated metal layer of a Ni layer and a Au layer that are stacked in this order), and a Ni/palladium (Pd)/Au layer (a laminated metal layer of a Ni layer, a Pd layer, and a Au layer that are stacked in this order). Furthermore, the surface treatment layer may be formed by performing anti-oxidation treatment such as an organic solderability preservative (OSP) process on the upper surface of the wiring layer 16 exposed in the openings 17x. By performing an OSP process, an organic coating of an azole compound, an imidazole compound or the like can be formed as the surface treatment layer. Furthermore, protruding electrodes such as metal posts (not depicted) may be formed on the upper surface of the wiring layer 16 exposed in the openings 17x.

The insulating layer 23 is an interlayer insulating layer formed on the second surface 10b of the glass core layer 10 to cover the wiring layer 22. The material and the thickness of the insulating layer 23 are, for example, the same as the material and the thickness, respectively, of the insulating layer 13. The insulating layer 23 may contain filler such as silica. The insulating layer 23 includes via holes 23x that are openings. The via holes 23x pierce through the insulating layer 23 to expose part of the lower surface of the wiring layer 22. The via holes 23x are, for example, recesses having the shape of a truncated cone, having a lower opening at the lower surface of the insulating layer 23 and an upper opening at the lower surface of the wiring layer 22. The lower opening is greater in diameter than the upper opening. The insulating layer 23 is a typical example of a second insulating layer according to this embodiment.

The wiring layer 24 fills in the via holes 23x to be electrically connected to the wiring layer 22, and extends onto the lower surface of the insulating layer 23 from within the via holes 23x. Specifically, the wiring layer 24 includes via interconnects that fill in the via holes 23x and wiring patterns formed on the lower surface of the insulating layer 23. The wiring patterns of the wiring layer 24 are electrically connected to the wiring layer 22 via the via interconnects. The material and the wiring pattern thickness of the wiring layer 24 are, for example, the same as the material and the thickness, respectively, of the wiring layer 12.

The insulating layer 25 is an interlayer insulating layer formed on the lower surface of the insulating layer 23 to cover the wiring layer 24. The material and the thickness of the insulating layer 25 are, for example, the same as the material and the thickness, respectively, of the insulating layer 13. The insulating layer 25 may contain filler such as silica. The insulating layer 25 includes via holes 25x that are openings. The via holes 25x pierce through the insulating layer 25 to expose part of the lower surface of the wiring layer 24. The via holes 25x are, for example, recesses having the shape of a truncated cone, having a lower opening at the lower surface of the insulating layer 25 and an upper opening at the lower surface of the wiring layer 24. The lower opening is greater in diameter than the upper opening.

The wiring layer 26 fills in the via holes 25x to be electrically connected to the wiring layer 24, and extends onto the lower surface of the insulating layer 25 from within the via holes 25x. Specifically, the wiring layer 26 includes via interconnects that fill in the via holes 25x and pads and interconnects formed on the lower surface of the insulating layer 25. The pads and the interconnects of the wiring layer 26 are electrically connected to the wiring layer 24 via the via interconnects. The material and the pad and interconnect thickness of the wiring layer 26 are, for example, the same as the material and the thickness, respectively, of the wiring layer 12.

The solder resist layer 27 is a protective insulating layer that is the outermost layer on the second side of the wiring substrate 1, and is formed on the lower surface of the insulating layer 25 to cover the wiring layer 26. The solder resist layer 27 includes openings 27x. Part of the lower surface of the wiring layer 26 is exposed in the openings 27x. The openings 27x have a circular planar shape, for example. The wiring layer 26 exposed in the openings 27x may be used as pads for electrical connections to a mounting board such as a motherboard. The above-noted metal layer may be formed or the above-noted organic coating may be formed by performing anti-oxidation treatment such as an OSP process on the lower surface of the wiring layer 26 exposed in the openings 27x. The thickness and the material of the solder resist layer 27 may be equal to the thickness and the material, respectively, of the solder resist layer 17. The solder resist layer 27 may contain filler such as silica.

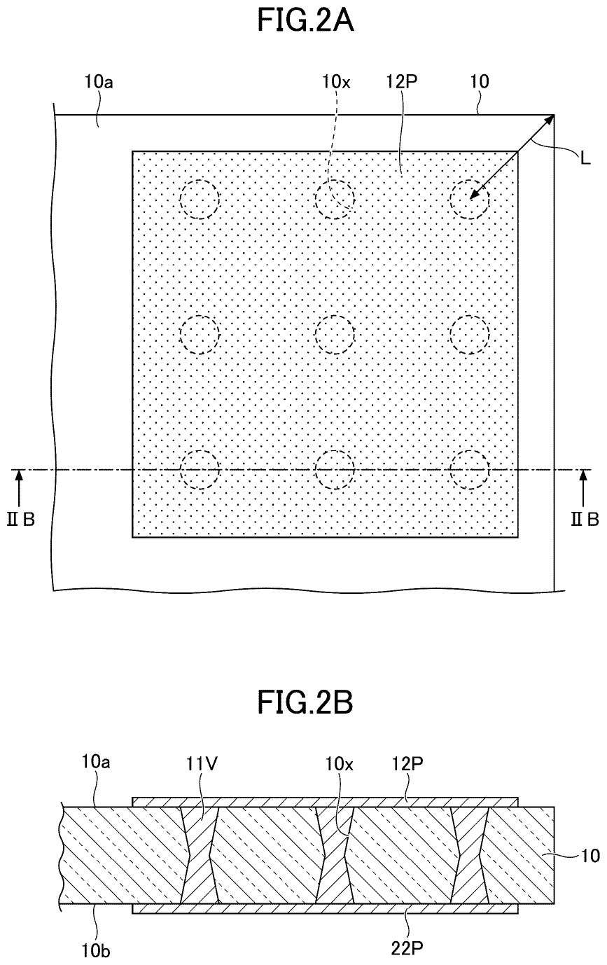

FIGS. 2A and 2B are diagrams illustrating part of the glass core layer 10 of the wiring substrate 1 according to the first embodiment. FIG. 2A is a plan view of the glass core layer 10 at a corner area R of FIG. 1A. FIG. 2B is a sectional view of the glass core layer 10, taken along the line IIB-IIB of FIG. 2A. The first surface 10a and the second surface 10b of the glass core layer 10 have the four corner areas R, each having a structure corresponding to the structure illustrated in FIGS. 2A and 2B.

Referring to FIGS. 2A and 2B, a first dummy pad 12P is placed in each of the corner areas R of the first surface 10a of the glass core layer 10. The first dummy pad 12P is part of the wiring layer 12, but is electrically independent of (isolated from) the other part of the wiring layer 12. A second dummy pad 22P is placed in each of the corner areas R of the second surface 10b of the glass core layer 10. The second dummy pad 22P is part of the wiring layer 22, but is electrically independent of (isolated from) the other part of the wiring layer 22. Dummy through vias 11V pierce through the glass core layer 10 to connect the first dummy pad 12P and the second dummy pad 22P.

The first dummy pad 12P and the second dummy pad 22P are, for example, at such positions as to be one over the other in a plan view. While the first dummy pad 12P and the second dummy pad 22P have a rectangular shape in a plan view according to the example of FIGS. 2A and 2B, the shape of the first dummy pad 12P and the second dummy pad 22P is not limited to this, and may be triangular, circular or the like in a plan view. The dummy through vias 11V may have a diameter of, for example, approximately 20 μm to approximately, 200 μm, at the positions of the first surface 10a and the second surface 10b. The pitch of the dummy through vias 11V may be approximately 1.5 times to approximately 5 times the diameter of the dummy through vias 11V.

The diameter of the dummy through vias 11V at the positions of the first surface 10a and the second surface 10b may be either equal to or different from the diameter of the through vias 11 for signals at the positions of the first surface 10a and the second surface 10b. The first dummy pad 12P, the second dummy pad 22P, and the dummy via interconnects 11V may be formed as a one-piece structure.

The coefficients of thermal expansion of the wiring layers and the insulating layers constituting the wiring substrate 1 are higher than the coefficient of thermal expansion of the glass core layer 10. The coefficient of thermal expansion of each of the wiring layers and insulating layers is, for example, more than or equal to 1.5 times the coefficient of thermal expansion of the glass core layer 10. Because of such a mismatch of coefficients of thermal expansion, cracks may be caused in the glass core layer 10 by changes in temperature. Cracks are likely to be caused particularly in the four corner areas R where thermal stress concentrates. Therefore, according to the wiring substrate 1, the first dummy pad 12P, the second dummy pad 22P, and the dummy through vias 11V are disposed in each of the four corner areas R.

In a plan view, a distance L from the apex of each corner area R of the first surface 10a of the glass core layer 10 to the center of the nearest dummy through via 11V is less than or equal to 17 times the maximum width of the dummy through vias 11V at the first surface 10a of the glass core layer 10. By arranging the dummy through vias 11V in an area to satisfy such a condition, cracks can be unlikely to be caused in the glass core layer 10.

The maximum width of the dummy through vias 11V is a diameter when the shape of the dummy through vias 11V at the position of the first surface 10a of the glass core layer 10 is circular, a major axis when the shape of the dummy through vias 11V at the position of the first surface 10a of the glass core layer 10 is elliptic, and the length of a diagonal when the shape of the dummy through vias 11V at the position of the first surface 10a of the glass core layer 10 is rectangular or square. Furthermore, when the shape of the dummy through vias 11V at the position of the first surface 10a of the glass core layer 10 is other than those described above, the length of the longest straight line that can be continuously drawn in the shape of the dummy through vias 11V at the position of the first surface 10a of the glass core layer 10 is defined as the maximum width.

In a plan view, the distance L from the apex of each corner area R of the first surface 10a of the glass core layer 10 to the center of the nearest dummy through via 11V is preferably less than or equal to 8 times the maximum width of the dummy through vias 11V at the first surface 10a of the glass core layer 10. By arranging the dummy through vias 11V in an area to satisfy such a condition, cracks can be more unlikely to be caused in the glass core layer 10.

Furthermore, in a plan view, the distance L from the apex of each corner area R of the first surface 10a of the glass core layer 10 to the center of the nearest dummy through via 11V is preferably more than or equal to 3 times the maximum width of the dummy through vias 11V at the first surface 10a of the glass core layer 10. By arranging the dummy through vias 11V in an area to satisfy such a condition, it is possible to stably form the through holes 10x and the dummy through vias 11V in the corner areas R.

In terms of increasing the effect of reducing cracks in the glass core layer 10, the number of the dummy through vias 11V per corner area is preferably more than or equal to 40, and more preferably, more than or equal to 100. Furthermore, in terms of increasing the effect of reducing cracks in the glass core layer 10, the dummy through vias 11V have a diameter of preferably more than or equal to 50 μm, and more preferably, approximately 100 μm at the positions of the first surface 10a and the second surface 10b.

By thus arranging the first dummy pad 12P, the second dummy pad 22P, and the dummy through vias 11V in each of the four corner areas of the glass core layer 10, cracks can be less likely to be caused in the glass core layer 10 because of the anchoring effect.

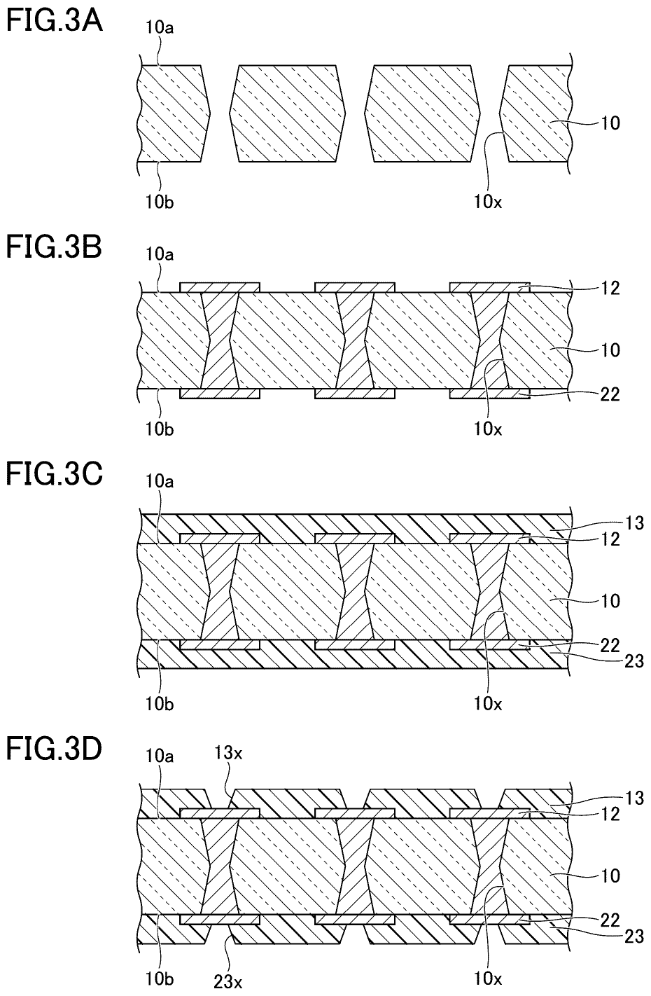

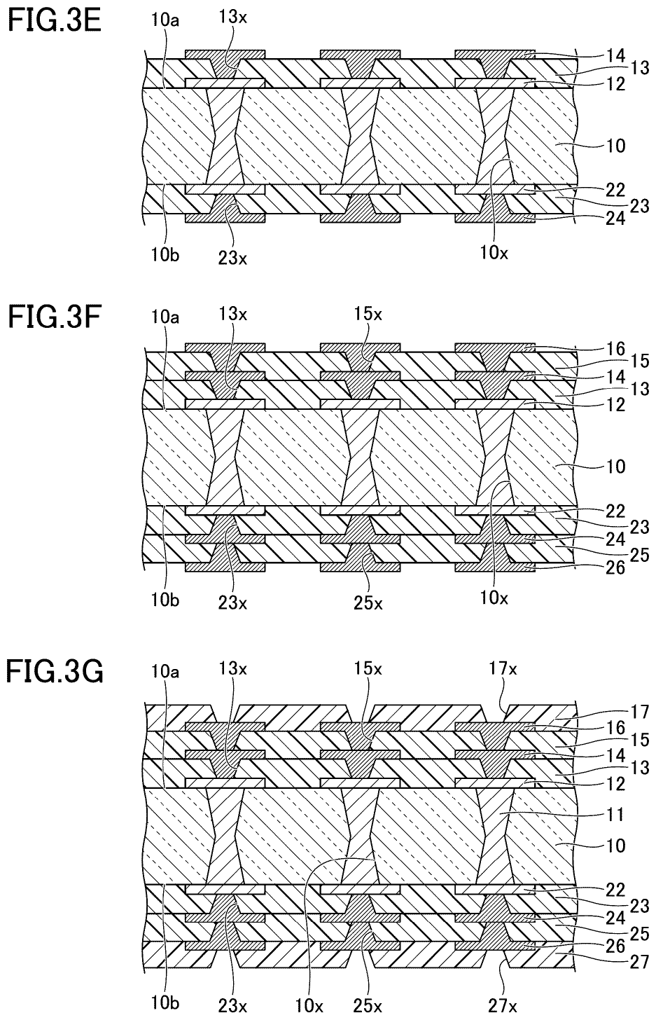

Next, a method of manufacturing a wiring substrate according to the embodiment is described. FIGS. 3A through 3G are diagrams illustrating a process of manufacturing a wiring substrate according to the embodiment, depicting a section corresponding to FIG. 1B.

As illustrated in FIGS. 3A through 3G, the wiring substrate 1 illustrated in FIGS. 1A and 1B may be manufactured by successively stacking wiring layers and insulating layers on the first surface 10a and the second surface 10b of the glass core layer 10, using, for example, a known build-up process.

First, in the process illustrated in FIG. 3A, the through holes 10x are formed in the glass core layer 10. The through holes 10x may be formed by, for example, forming first recesses in the first surface 10a of the glass core layer 10 by exposing the first surface 10a to laser light, thereafter forming second recesses in the second surface 10b of the glass core layer 10 by exposing the second surface 10b to laser light, and causing the first recesses and the second recesses to communicate with each other near the center of the glass core layer 10 in its thickness direction. For example, a CO₂ laser may be used to form the through holes 10x.

Next, in the process illustrated in FIG. 3B, the through vias 11 and the wiring layers 12 and 22 are formed in and on the glass core layer 10, using, for example, a known semi-additive process. Specifically, a seed layer (copper or the like) covering the first surface 10a and the second surface 10b of the glass core layer 10 and the inner wall faces of the through holes 10x is formed by, for example, electroless plating, sputtering or the like. Then, a resist layer having openings is formed on the seed layer on the first surface 10a and the second surface 10b of the glass core layer 10. Then, an electroplating layer (copper or the like) is formed on the seed layer exposed in the openings of the resist layer by electroplating using the seed layer as a power feed layer. Next, after removing the resist layer, etching is performed using the electroplating layer as a mask to remove the seed layer exposed from the electroplating layer. As a result, the electroplating layer formed on the seed layer fills in the through holes 10x to form the through vias 11, and the seed layer and the electroplating layer are stacked to form the wiring layer 12 and the wiring layer 22 on the first surface 10a and the second surface 10b, respectively, of the glass core layer 10. Furthermore, in this process, as well as the through vias 11 and the wiring layers 12 and 22, the dummy through vias 11V, the first dummy pad 12P, and the second dummy pad 22P are formed in the four corner areas of the glass core layer 10.

Next, in the process illustrated in FIG. 3C, a laminate of non-photosensitive thermosetting resin whose main component is an organic material, such as a semi-cured film of epoxy resin or the like, is formed on the first surface 10a of the glass core layer 10 to cover the wiring layer 12, and is cured to form the insulating layer 13. Furthermore, a laminate of non-photosensitive thermosetting resin whose main component is an organic material, such as a semi-cured film of epoxy resin or the like, is formed on the second surface 10b of the glass core layer 10 to cover the wiring layer 22, and is cured to form the insulating layer 23. In place of a laminate of an epoxy resin film, epoxy resin liquid or paste may be applied and thereafter cured to form the insulating layers 13 and 23.

Next, in the process illustrated in FIG. 3D, the via holes 13x, which are openings penetrating through the insulating layer 13 to expose the upper surface of the wiring layer 12, are formed in the insulating layer 13. Furthermore, the via holes 23x, which are openings penetrating through the insulating layer 23 to expose the lower surface of the wiring layer 22, are formed in the insulating layer 23. The via holes 13x and 23x may be formed by, for example, laser processing using a CO₂ laser. After the formation of the via holes 13x and 23x, a desmear process is preferably performed to remove resin residue sticking to the surfaces of the wiring layers 12 and 22 exposed at the bottom of the via holes 13x and 23x.

Next, in the process illustrated in FIG. 3E, the wiring layer 14, which fills in the via holes 13x to be electrically connected to the wiring layer 12 and extends onto the upper surface of the insulating layer 13 from within the via holes 13x, is formed. The wiring layer 14 includes the via interconnects filling in the via holes 13x and the wiring patterns formed on the upper surface of the insulating layer 13. Furthermore, the wiring layer 24, which fills in the via holes 23x to be electrically connected to the wiring layer 22 and extends onto the lower surface of the insulating layer 23 from within the via holes 23x, is formed. The wiring layer 24 includes the via interconnects filling in the via holes 23x and the wiring patterns formed on the lower surface of the insulating layer 23. The wiring layers 14 and 24 may be formed using a wiring formation process among various types of wiring formation processes including a semi-additive process and a subtractive process.

Next, in the process illustrated in FIG. 3F, the insulating layer 15, the via holes 15x, the wiring layer 16, the insulating layer 25, the via holes 25x, and the wiring layer 26 are formed in the same manner as illustrated in FIGS. 3C through 3E.

Next, in the process illustrated in FIG. 3G, the solder resist layer 17 is formed on the upper surface of the insulating layer 15 to cover the wiring layer 16. Furthermore, the solder resist layer 27 is formed on the lower surface of the insulating layer 25 to cover the wiring layer 26. The solder resist layer 17 may be formed by, for example, applying photosensitive epoxy insulating resin liquid or paste on the upper surface of the insulating layer 15 to cover the wiring layer 16 by screen printing, roll coating, spin coating or the like. Alternatively, the solder resist layer 17 may be formed by, for example, forming a laminate of a photosensitive epoxy insulating resin film on the upper surface of the insulating layer 15 to cover the wiring layer 16. The solder resist layer 27 may be formed in the same manner as the solder resist layer 17.

Next, the solder resist layers 17 and 27 are exposed to light and developed to form the openings 17x, which expose part of the upper surface of the wiring layer 16, in the solder resist layer 17 and the openings 27x, which expose part of the lower surface of the wiring layer 26, in the solder resist layer 27. The above-noted metal layer may be formed by electroless plating or the like, or anti-oxidation treatment such as an OSP process may be performed to form an organic coating, on the upper surface of the wiring layer 16 exposed in the openings 17x and the lower surface of the wiring layer 26 exposed in the openings 27x on an as-needed basis. As a result, the wiring substrate 1 is obtained.

Next, a variation of the embodiment is described. According to the variation, an alignment mark is formed in a dummy pad. In the following description, a description of the same elements or components as those of the above-described embodiment may be omitted.

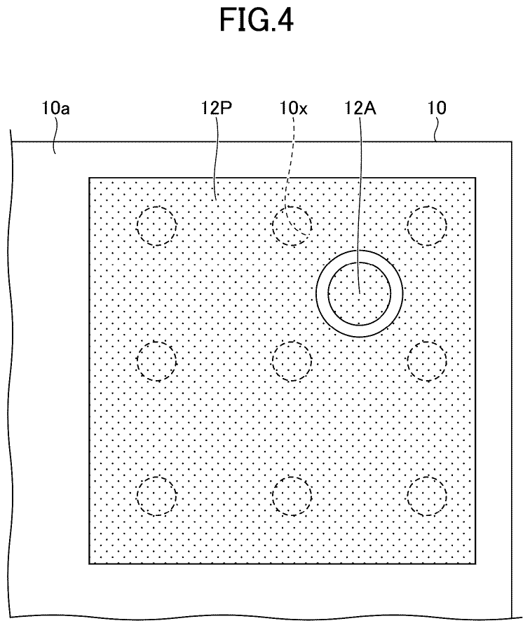

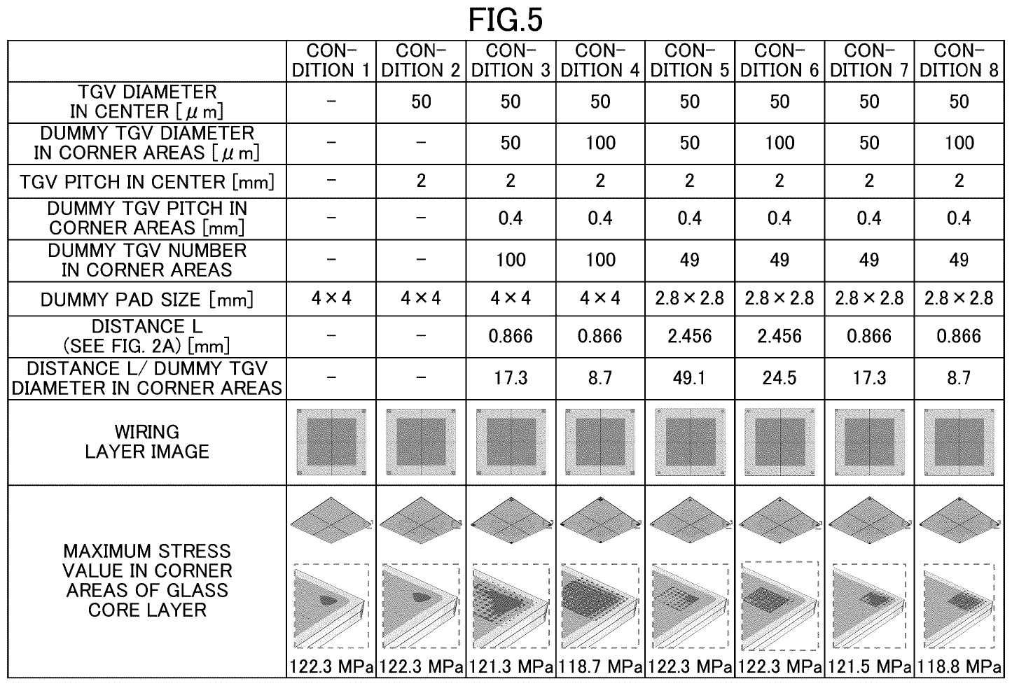

FIG. 4 is a plan view of part of the glass core layer of a wiring substrate according to the variation. Referring to FIG. 4, in a plan view, an alignment mark 12A is provided in the area where the first dummy pad 12P is formed. The alignment mark 12A has, for example, a circular shape, and the first surface 10a is annularly exposed around the circular shape. The alignment mark 12A may alternatively have a rectangular shape, a cross shape, or the like.

The alignment mark 12A may be provided in each of the four corner areas R of the first surface 10a of the glass core layer 10, for example. The alignment mark 12A may be provided in each of two diagonal corner areas R of the first surface 10a of the glass core layer 10, for example. The provision of the alignment marks 12A facilitates alignment in each of the processes of manufacturing the wiring substrate 1. The same alignment mark as the alignment mark 12A may be provided in the area where the second dummy pad 22P is formed in a plan view.

### [Simulation]

A linear static analysis is conducted using ABAQUS 2023 with respect to a wiring substrate having the structure illustrated in FIGS. 1A and 1B. The external dimensions of the wiring substrate are 75 mm square, and a laminated structure with symmetrical top and bottom layers of the glass core layer is assumed. Furthermore, copper wiring layers are assumed. With respect to Conditions 1 through 8 illustrated in FIG. 5, it is checked how much the maximum stress value generated in the corner areas of the glass core layer when the temperature of the wiring substrate is decreased from 180° C. to 25° C. changes depending on the presence or absence of dummy through vias, etc. The physical properties of each layer at room temperature are as illustrated in Table 1. The through vias have a circular planar shape. Hereinafter, the through vias are referred to as “TGVs” for simplicity.

TABLE 1

| | Elastic | Poisson's | CTE |
|---|---|---|---|
| | modulus [MPa] | ratio- | [ppm/° C.] |
| Solder resist | 8500 | 0.31 | 28.0 |
| layer | | | |
| Wiring layer | 117700 | 0.34 | 17.2 |
| Insulating | 13000 | 0.27 | 20.0 |
| layer | | | |
| Glass core | 77000 | 0.22 | 3.7 |
| layer | | | |

With respect to each of Conditions 1 through 8, a wiring pattern of 50 mm square is placed in the center and a dummy pad of 4 mm square or 2.8 mm square is placed in each of the four corner areas of each of the upper surface and the lower surface of the glass core layer in a plan view. Condition 1 is the case where no TGVs or dummy TGVs are disposed in the glass core layer. Condition 2 is the case where the TGVs are disposed in the center and no dummy TGVs are disposed in the corner areas of the glass core layer in a plan view. Conditions 3 through 8 are the case where the TGVs are disposed in the center and the dummy TGVs are disposed in the corner areas of the glass core layer in a plan view.

FIG. 5 indicates the TGV diameter, pitch and number, and the distance L (see FIG. 2A), along with the simulation result, of each condition. In “MAXIMUM STRESS VALUE IN CORNER AREAS OF GLASS CORE LAYER” in FIG. 5, a perspective view depicts the entirety of the glass core layer and an enlarged view of one corner area is presented in the area enclosed by the dashed line. Furthermore, the number below the area enclosed by the dashed line is the maximum stress value generated in the corner areas of the glass core layer determined by this simulation. The following results are read from FIG. 5.

Disposing the TGVs in the center but without the dummy TGVs in the corner areas as in Condition 2 does not change the maximum stress value generated in the corner areas of the glass core layer from that of Condition 1 where no TGVs are disposed. That is, the structure of Condition 2 produces no effect of preventing or reducing the generation of cracks in the glass core layer.

Disposing the dummy TGVs in the corner areas with a relatively large “DISTANCE L/DUMMY TGV DIAMETER IN CORNER AREAS” as in Condition 5 and Condition 6 does not change the maximum stress value generated in the corner areas of the glass core layer from that of Condition 1 where no TGVs are disposed. That is, the “DISTANCE L/DUMMY TGV DIAMETER IN CORNER AREAS” counts in preventing or reducing the generation of cracks in the glass core layer.

Conditions 3 and 7 indicate that when the dummy TGVs are disposed in the corner areas and the “DISTANCE L/DUMMY TGV DIAMETER IN CORNER AREAS” is 17.3, the maximum stress value generated in the corner areas of the glass core layer is reduced from that of Condition 1 where no TGVs are disposed. Furthermore, Conditions 4 and 8 indicate that when the dummy TGVs are disposed in the corner areas and the “DISTANCE L/DUMMY TGV DIAMETER IN CORNER AREAS” is 8.7, the maximum stress value generated in the corner areas of the glass core layer is further reduced compared with Conditions 3 and 7.

Conditions 3 and 4 and Conditions 7 and 8 indicate that when the distance L is the same, the maximum stress value generated in the corner areas of the glass core layer decreases as the diameter of the dummy TGVs disposed in the corner areas increases. Furthermore, it is also indicated that the dummy pad size does not have a significant effect on the maximum stress value generated in the corner areas of the glass core layer.

Thus, in the structure where dummy pads are provided one in each corner area of each of opposite (first and second) surfaces of a glass core layer and the dummy pads on the opposite surfaces are connected by dummy TGVs, the distance from the apex of each corner area of the first surface of the glass core layer to the center of the nearest dummy TGV is preferably less than or equal to 17 times the diameter of the dummy TGVs at the first surface of the glass core layer in a plan view. This can reduce the maximum stress value generated in the corner areas of the glass core layer.

The distance from the apex of each corner area of the first surface of the glass core layer to the center of the nearest dummy TGV is preferably less than or equal to 8 times the diameter of the dummy TGVs at the first surface of the glass core layer in a plan view. This can further reduce the maximum stress value generated in the corner areas of the glass core layer.

When the temperature of the wiring substrate is reduced from 180° C. to 25° C., the dummy TGVs having a higher coefficient of thermal expansion than the glass core layer tend to contract more than the glass core layer. At this point, the dummy pads placed on the opposite surfaces of the glass core layer apply a force in a direction to compress the glass core layer from the opposite sides of the glass core layer. In general, the glass core layer is pulled upward and downward to crack. It is believed that the glass core layer is less likely to be pulled upward and downward because of the force in the direction to compress the glass core layer applied by the dummy pads and that cracks are therefore less likely to be caused in the glass core layer.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority or inferiority of the invention. Although one or more embodiments of the present invention have been described in detail, it should be understood that the various changes, substitutions, and alterations could be made hereto without departing from the spirit and scope of the invention.

For example, the present invention may be applied to a wiring substrate having a structure where wiring layers and insulating layers are stacked on one side of the glass core layer. In this case as well, cracks are less likely to be caused in the glass core layer.

What is claimed is:

1. A wiring substrate comprising:
a glass core layer;
a first wiring layer on a first surface of the glass core layer;
a first insulating layer covering the first wiring layer;
a second wiring layer on a second surface of the glass core layer on an opposite side from the first surface;
a second insulating layer covering the second wiring layer;
a plurality of first dummy pads provided one in each of corner areas of the first surface of the glass core layer, the plurality of first dummy pads being part of the first wiring layer and electrically independent of the other part of the first wiring layer;
a plurality of second dummy pads provided one in each of corner areas of the second surface of the glass core layer, the plurality of second dummy pads being part of the second wiring layer and electrically independent of the other part of the second wiring layer; and
a plurality of dummy through vias piercing through the glass core layer to connect the plurality of first dummy pads and the plurality of second dummy pads,
wherein the first insulating layer and the second insulating layer include an organic material as a main component, and
in each of the corner areas of the first surface, a distance from an apex of the corner area to a center of a dummy through via nearest to the apex among the plurality of dummy through vias is less than or equal to 17 times a maximum width of the plurality of dummy through vias at the first surface in a plan view.

2. The wiring substrate as claimed in claim 1, wherein the distance is less than or equal to 8 times the maximum width.

3. The wiring substrate as claimed in claim 1, wherein the distance is more than or equal to 3 times the maximum width.

4. The wiring substrate as claimed in claim 1, wherein a coefficient of thermal expansion of each of the first wiring layer, the second wiring layer, the first insulating layer, and the second insulating layer is more than or equal to 1.5 times a coefficient of thermal expansion of the glass core layer.

5. The wiring substrate as claimed in claim 1, wherein an alignment mark is provided in each of an area where the plurality of first dummy pads are formed and an area where the plurality of second dummy pads are formed.

6. The wiring substrate as claimed in claim 5, wherein the alignment mark has a circular shape, a rectangular shape, or a cross shape.

7. The wiring substrate as claimed in claim 1, wherein an alignment mark is formed in the first dummy pad in each of the corner areas of the first surface and is provided in the second dummy pad in each of the corner areas of the second surface.

8. The wiring substrate as claimed in claim 1, wherein an alignment mark is formed in the first dummy pad in each of two diagonal corner areas among the corner areas of the first surface and is provided in the second dummy pad in each of two diagonal corner areas among the corner areas of the second surface.

9. The wiring substrate as claimed in claim 1, wherein the plurality of dummy through vias have a circular shape, an elliptic shape, a rectangular shape, or a square shape at the first surface.
